(19) United States
(12) Patent Application Publication
(10) Pub. No.: US 2004/0160231 A1
(43) Pub. Date: Aug. 19, 2004

(54) Capacitance measurement system

(76) Inventors: Yukoh Iwasaki, Tokyo (JP); Tomonobu Hiramatsu, Tokyo (JP)

Correspondence Address: Paul D. Greeley, Esq., Ohlandt , Greeley, Ruggiero & Perle, L.L.P., 10th Floor, One Landmark, Stamford, CT, 06901-2682, US

(21) Appl. No.: 10/725,799

(22) Filed: Dec. 2, 2003

(30) Foreign Application Priority Data
Dec. 2, 2002 (JP) 2002-350405

(51) Int. Cl. G01R 27/26

(52) U.S. Cl. 324/658

(57) ABSTRACT

To provide a capacitance measurement system with which capacitance is measured at a high speed using a semiconductor parametric test system. The capacitance measurement system has test head 104 comprising multiple input/output terminals 152 and 154 that connect the element under test 114, source and measure unit 110 that supplies voltage or current, capacitance measurement unit 108 with an impedance measurement function, and switching matrix 112 that connects the multiple input/output terminals, the source and measure unit, and the capacitance measurement unit.

### BACKGROUND OF THE INVENTION

1. Field of the Invention

The present invention pertains to a semiconductor process monitor and more specifically, to a system with which capacitance can be measured during the semiconductor production process at high precision and fast speed.

2. Description of the Related Art

A capacitance measurement system that uses a semiconductor parametric test system such as that shown in FIG. 4 has been used for capacitance measurement during semiconductor production processes, such as the evaluation of the oxide-film capacitance of a semiconductor. Conventional capacitance measurement system 400 herein comprises inside test head 406 a source and measure unit (SMU) 412 that supplies and/or measures voltage or current as a function of controlling the current or controlling the voltage, a switching matrix (SWM) 410 that has the function of selecting the input/output terminals from the subject under test or device under test (DUT) 414 and switching diverse measurement paths with the measurement equipment, such as the SMU, and a test head controller (TH controller) 408 that controls the SMU and SWM. In addition to test head 406, this capacitance measurement system 400 comprises external capacitance measurement equipment 404 and external controller 402 having a computer or similar device. Connection lines 420, 422, 424, and 426 between each block represent the control lines and connection lines 430, 431, 432, 434, 436, 438, and 440 represent the connection lines relating to the measurement of each block. Terminal 450 is the outside connection terminal of SWM 410 and of the multiple input/output terminals of the test head 406, terminals 452 and 454 are the input terminals that determine the formation of a connection with DUT 414 (for instance, refer to p. 3 of Hewlett-Packard Company, “HP4072A Advanced Parametric Tester with HP SPECS,” Catalog (English), US, 1999 and pp. 2 and 3 of Agilent Technologies, “Agilent 4070 Series Accurate Capacitance Characterization at the Wafer Level,” Application Note 4070-2 (English), US, 2000 (both incorporated herein by reference)).

External capacitance measurement equipment 404 is generally placed outside test head 406 and housed in a rack together with an external controller for purposes of connection with external controller 402. Therefore, taking into consideration the layout, a cable as long as 4 m is needed to connect external capacitance measurement equipment 404 and outside connection terminal 450. Moreover, an impedance meter, such as the Agilent 4284A, is used as an example of an external capacitance measurement equipment 404.

It should be noted that the connection between each block is schematically represented with only one or two lines in FIG. 4, such as the connection line between external capacitance measurement equipment 404 and SWM 410. However, there are also cases where SMU 412 has multiple channels. It should be noted that the same is true also for the rest of the block diagrams other than FIG. 4.

A diagram of the transfer of data from capacitance measurement by the system in FIG. 4 is shown in FIG. 5. The time course is shown schematically from the top to the bottom of the y-axis in the diagram. First, connection command 1 502 is transmitted from external controller 402 to TH controller 408, this command is received, and TH controller 408 transmits connection command 2 504 to SWM 410. After a specific wait time, WAIT 506, TH controller 408 returns message 508 acknowledging that the connection was completed (connection Ack) to each controller 402. Next, external controller 402 transmits capacitance measurement command 510 to external capacitance measurement equipment 404 and external capacitance measurement equipment 404 performs measurement over time 512. The results are then returned to external controller 402 as measured-value transmission 514. Here, capacitance values based on a two-element model, as shown in FIG. 3 of Agilent Technologies, “Agilent 4070 Series Accurate Capacitance Characterization at the Wafer Level,” Application Note 4070-2 (English), US, 2000, are returned to external controller 402.

Data 502, 508, 510, and 514 are transferred to an independent controller or measurement equipment. The central processing unit (CPU) of each device manages the transfer protocol until there is synchronization and therefore, the transfer time is long when compared to transfer 504 with the SWM, which is a module that does not have a central processing unit.

Moreover, external capacitance measurement equipment 404 is in the same rack as the external controller and therefore, the measurement line connecting with SWM 410 is as long as 4 m. Therefore, the wait time during the measurement cannot be curtailed and there are limits as to how high the measurement accuracy can be. Moreover, the wafer probing machine housing the device under test connected to the test head has become large in recent years and as a result, there are cases in which this 4 m measurement line is too short and interferes with placement of the rack.

Furthermore, external capacitance measurement equipment 404 returns the values for each element that has been converted to a two-element model as the circuit model, such as the gate-oxide film DUT; therefore, of the subjects under test in recent years, measurement using the appropriate terminal model of 3 elements or more cannot be performed when resistance is low (for instance, refer to Mieko Matsumura, et al., “Negative-Capacitance Effect in Forward-Biased Metal Oxide Semiconductor,” Jpn. J. Appl. Phys. Vol. 39 (2000) pp. L123-L125, Part 2, No. 2B, Feb. 15, 2000, incorporated herein by reference).

### SUMMARY OF THE INVENTION

An object of the present invention is to propose a capacitance measurement system with which capacitance can be measured at high precision using a semiconductor parametric test system.

Still another object of the present invention is to propose a capacitance measurement system with which capacitance measurement can be performed based on a multi-element model of 3 elements or more using a semiconductor parametric test system.

Yet another object of the present invention is to propose a capacitance measurement system with which the problem of restrictions in terms of placement attributed to the connection cable between the test head and the external capacitance measurement system is solved.

In order to solve the above-mentioned problems, the capacitance measurement system of the present invention has a test head comprising multiple input/output terminals that connect the terminal under test, a source and measure unit that supplies voltage or current, a capacitance measurement unit with an impedance measurement function, and a switching matrix that connects the multiple input/output terminals, the source and measure unit, and the capacitance measurement unit.

The present invention further includes the embodiment wherein the above-mentioned test head comprises a test head controller that controls the source and measure unit, the capacitance measurement unit, and the switching matrix, and the embodiment whereby the test head comprises the calibration terminal of the capacitance measurement unit and the external connection terminal of the switching matrix, and the capacitance measurement unit and switching matrix are connected via this calibration terminal and this external connection terminal.

The capacitance measurement unit of the present invention further comprises the embodiment whereby the absolute value and phase of impedance of a device under test are transmitted to the test head controller, and the embodiment wherein it comprises an external controller that is connected to the test head and controls the test head controller.

The capacitance measurement unit of the present invention also includes the embodiment whereby it transmits the values of the real part and the imaginary part of impedance of the device under test to the test head controller.

### BRIEF DESCRIPTION OF THE DRAWINGS

FIG. 1 is a block diagram showing an example of an embodiment of the present invention;

FIG. 2 is a diagram showing the data transfer at the time of the measurement operation in FIG. 1;

FIG. 3 is a block figure showing an example of another preferred embodiment of the present invention;

FIG. 4 is a block figure showing the capacitance measurement system of the prior art; and

FIG. 5 is a diagram showing the data transfer at the time of the measurement operation in FIG. 4.

### DETAILED DESCRIPTION OF THE INVENTION

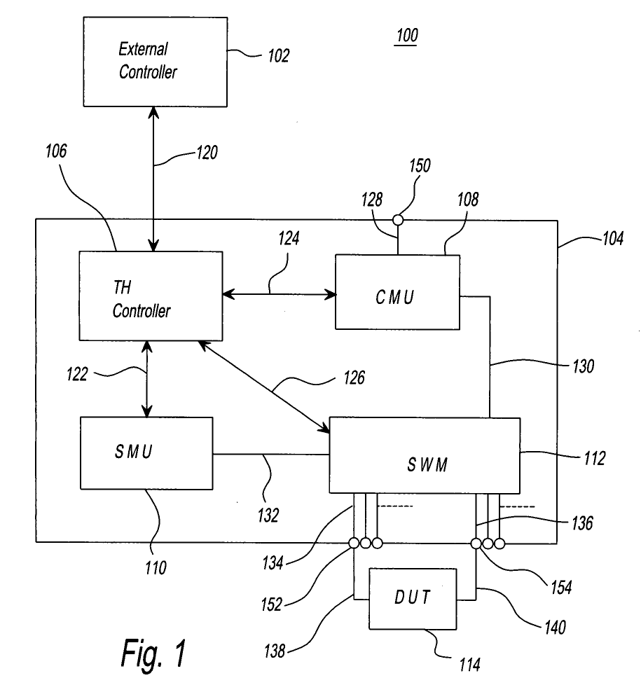

Capacitance measurement system 100, which is one embodiment of the present invention, is shown in FIG. 1. Capacitance measurement system 100 comprises test head 104 and external controller 102. Test head 104 comprises SMU 110, capacitance measurement unit (CMU) 108, SWM 112, and TH controller 106. Terminal 150 indicates the calibration terminal of the CMU and terminals 152 and 154 show the input/output terminals of DUT 114 of test head 104. Furthermore, there are multiple input/output terminals at test head 104 and these are connected to the respective SWM 112. The test head further has control lines 120, 122, 124, and 126 between each block and connection lines for measurement 128, 130, 132, 134, 136, 138, and 140 between each block. It should be noted that the connection between each block is schematically represented with only one or two lines in FIG. 1. However, although SMU 110 and/or CMU 108 is/are schematically represented with only one channel, they can also have multiple channels. This is also true for all of the block diagrams herein.

CMU 108 is not an independent measurement equipment comprising a CPU such as external capacitance measurement equipment 404, but rather is made as a module within a test head that does not comprise a CPU. That is, many commands are used with conventional independent measurement equipment because they have diverse functions and processing takes time because these commands are translated by the CPU based on programs. However, if conventional independent measurement equipment was made as modules (e.g., CMU 108 and SMU 110) inside a test head, various functions can be mounted as hardware and executed at high speed using a gate array and the like, because the function can be limited. Furthermore, conventional independent measurement equipments need to support diverse devices for and therefore, it is necessary to mount a handshake, which is a popular solution but is also tedious. In contrast to this, the devices connected to modules inside a test head are limited and therefore, handshake processing is optimized and high-speed intelligent execution is possible. In addition, CMU 108 also has the function of returning the absolute value and the phase or the real part and the imaginary part of impedance to TH controller 106 as the result of capacitance measurement.

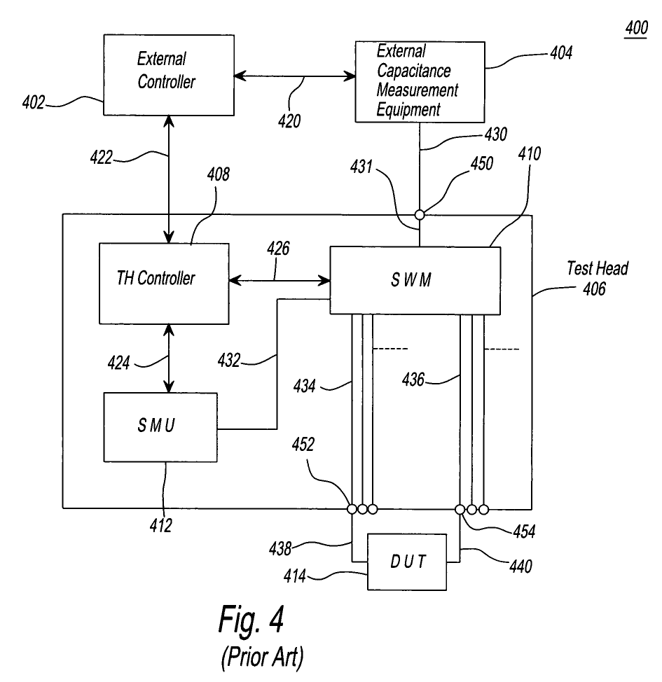

Furthermore, by housing CMU 108 in test head 104, it is possible to wire connection cable 130 for measurement between CMU 108 and SWM 112 inside test head 104 and shorten the connecting cable to approximately 50 cm. As a result, the connecting cable is much shorter than connection cable 430 in FIG. 4, and this is very effective in terms of measurement wait time and measurement precision.

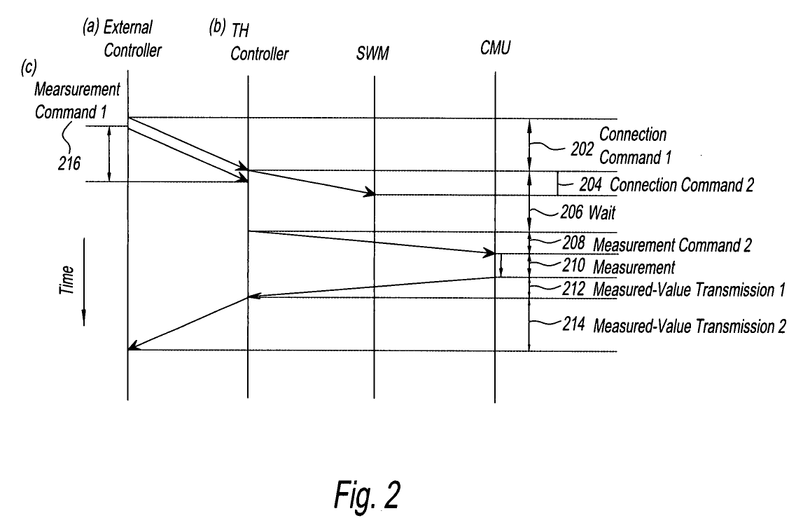

A schematic diagram of transfer of data obtained by capacitance measurement with the system shown in FIG. 1 is shown in FIG. 2. The y-axis shows the passage of time schematically from the top to the bottom. First, connection command 1, 202, is transmitted from external controller 102 to TH controller 106, this command is received and TH controller 106 transmits connection command 2 204 to SWM 112. Then external controller 102 transmits measurement command 1 to TH controller 106. TH controller 106 receives this command and transmits measurement command 2, 208, to CMU 108 once a specific wait time, WAIT 206, after transmission of the previous connection command 2 has passed. CMU 108 performs measurement in time 210 and the measurement results are transmitted to TH controller 106 as measured-value transmission 1, 212. This transmission is received and TH controller 106 returns the measured value to external controller 102 by measured-value transmission 2, 214. When this capacitance measurement system 100 measures the capacitance based on a multi-element model rather than a 2-element circuit model, such as a gate-oxide film, CMU 108 returns the absolute value and phase or real part and imaginary part of impedance to TH controller 106 as the measured values.

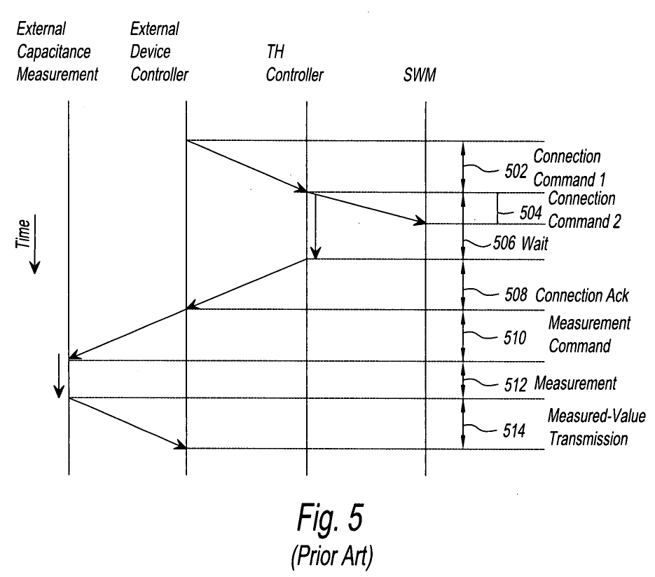

The transmission destination of data transmission 202, 214, and 216 in FIG. 2 is an independent controller and therefore, the CPU inside TH controller 106 manages the transmission protocol to obtain synchronism, so that the transfer time is longer when compared to transfer (204, 208, 212) with SWM 112 or CMU 108, which are modules without a CPU. Nevertheless, when compared to FIG. 5, there is a reduction in data transfer between equipment with a CPU, and therefore, the overall data transfer time can be curtailed.

Furthermore, SWM 112 and CMU 108 are both internal modules connected to TH controller 106 and therefore, connection Ack 508 (FIG. 5) acknowledging execution of the connection command can also be omitted for even further curtailment of the transfer time. Consequently, because the connection line between CMU 108 and SWM 112 is short, the wait time during measurement can be curtailed and measurement 210 can be shorter than measurement 512 in FIG. 5.

In addition, CMU 108 does not report the capacitance measured value based on a specific element model, but can also report the absolute value and phase or real part and imaginary part of impedance of the device under test, and therefore, capacitance converted to the value of a 3-element model or any element model can be obtained by TH controller 106 or external controller 102.

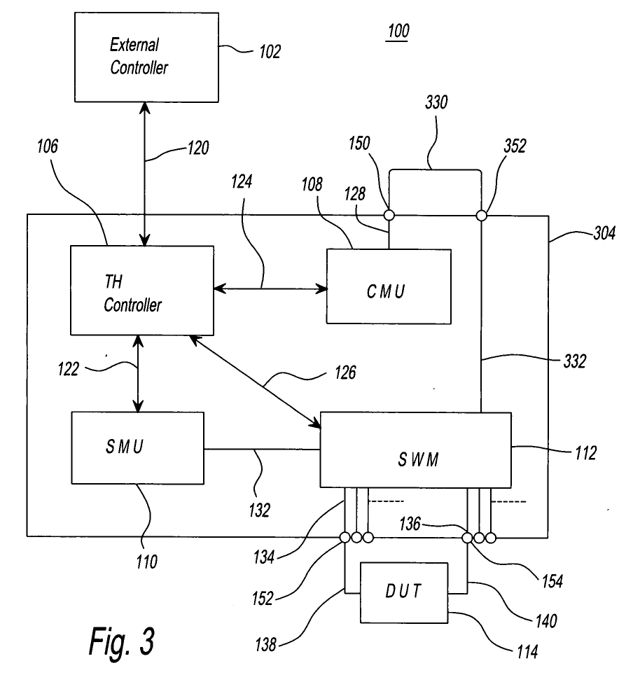

Capacitance measurement system 300 based on another embodiment of the present invention is shown in FIG. 3. Here, blocks with the same function as in FIG. 1 are shown using the same reference numbers. What is different from FIG. 1 is that connection line for measurement 130 from CMU 108 to SWM 112 is replaced by external connection terminal 352 of SWM 112 in test head 304, and CMU 108 and SWM 112 are connected by connecting lines 128, 330, and 332. For instance, a cable that is approximately 20 cm is used for connection line 330.

By means of this type of structure, the same result of high-speed measurement as with the data transmission diagram in FIG. 2 can be realized with capacitance measurement system 300, and the connection between CMU 108 and SWM 112 can be made substantially shorter than with the prior art shown in FIG. 4. Therefore, the wait time during measurement is curtailed and high-precision measurement is possible. In addition, the path from CMU 108 to calibration terminal 150 is calibrated, and therefore, measurement with even higher precision is possible. In addition, it is possible to connect equipment that is the equivalent of external capacitance measurement equipment 404 in FIG. 4 with external connection terminal 352 of SWM 112 in order to know the correlation with data measured by the conventional capacitance measurement system in FIG. 4.

In summary, the present invention proposes a capacitance measurement system that is capable of high-speed, high-precision capacitance measurement using a semiconductor parametric test system. Moreover, a capacitance measurement system is proposed that uses a semiconductor parametric test system with which, in addition to the above-mentioned operation, the correlation with data between the system and a conventional system can be easily determined.

Furthermore, a capacitance measurement system is proposed that is capable of capacitance measurement with a model comprising any number of elements using a semiconductor parametric test system. In addition, the problem of contradictory requirements that the connection line that connects the test head and the external capacitance measurement unit should be long in terms of layout but should be short in terms of measurement accuracy is resolved, making high-precision measurement possible, by housing the capacitance measurement unit in the test head.

What is claimed is:

1. A capacitance measurement system having a test head comprising:
a plurality of input/output terminals connecting a device under test;
a source and measure unit supplying voltage or current;
a capacitance measurement unit having an impedance measurement function; and
a switching matrix connecting said plurality of input/output terminals, said source and measure unit, and said capacitance measurement unit.

2. The capacitance measurement system of claim 1, wherein said test head comprises a test head controller for controlling said source and measure unit, said capacitance measurement unit, and said switching matrix.

3. The capacitance measurement system according to claim 1, wherein said test head comprises a calibration terminal of said capacitance measurement unit and an external connection terminal of said switching matrix, and said capacitance measurement unit and said switching matrix are connected via said calibration terminal and said external connection terminal.

4. The capacitance measurement system according to claim 1, wherein said capacitance measurement unit transmits an absolute value and phase of impedance of said device under test to said test head controller.

5. The capacitance measurement system according to claim 1, further comprising an external controller that is connected to said test head and controls said test head controller.

6. The capacitance measurement system according to claim 1, wherein said capacitance measurement unit transmits a value of a real part and an imaginary part of an impedance of said device under test to said test head controller.

7. The capacitance measurement system according to claim 2, wherein said capacitance measurement unit transmits an absolute value and phase of impedance of said device under test to said test head controller.

8. The capacitance measurement system according to claim 2, further comprising an external controller that is connected to said test head and controls said test head controller.

9. The capacitance measurement system according to claim 2, wherein said capacitance measurement unit transmits a value of a real part and an imaginary part of an impedance of said device under test to said test head controller.
